(19) United States
(12) Patent Application Publication
(10) Pub. No.: US 2026/0309785 A1
(43) Pub. Date: Oct. 8, 2026

(54) Method for Estimating State of Rechargeable Battery

(71) Applicant: TOYOTA BATTERY Co., Ltd., Shizuoka (JP)

(72) Inventor: Keita Matsumoto, Toyohashi-shi (JP)

(21) Appl. No.: 19/544,985

(22) Filed: Feb. 19, 2026

(30) Foreign Application Priority Data
Apr. 8, 2025 (JP) 2025063662

(51) Int. Cl. G01R 31/367; G01R 31/374; G01R 31/378; G01R 31/3835; G01R 31/392

(52) U.S. Cl. CPC G01R 31/367; G01R 31/374; G01R 31/378; G01R 31/3835; G01R 31/392

(57) ABSTRACT

Prior to processing, a UKF processor obtains a positive-electrode OCP curve OCPₚ and a negative-electrode OCP curve OCPₙ. The positive-electrode OCP curve and the negative-electrode OCP curve are each differentiated. A standard deviation Q_{Cs,ave,p} and a standard deviation Q_{Cs,ave,n} are set to initial values. Then, based on θₚ and θₙ, dV_{p,abs}/dθ(θₚ) and dV_{n,abs}/dθ(θₙ) are calculated. The standard deviation Q_{Cs,ave,p} is multiplied by dVₚ/dθ(θₚ). Further, Q_{Cs,ave,n} is multiplied by dVₙ/dθ(θₙ). A nonlinear Kalman filter corrects C_{s,ave,p} and C_{s,ave,n}. The corrected parameters are used to calculate SOC and FCC.

### CROSS-REFERENCE TO RELATED APPLICATIONS

This application is based upon and claims the benefit of priority from prior Japanese Patent Application No. 2025-063662, filed on Apr. 8, 2025, the entire contents of which are incorporated herein by reference.

### BACKGROUND

### 1. Field

The following description relates to a method for estimating a state of a rechargeable battery easily and accurately.

### 2. Description of Related Art

In a rechargeable battery, such as a lithium-ion battery, the full charge capacity (FCC) decreases due to deterioration resulting from use. Here, the FCC corresponds to an amount of electric charge that is obtainable from the rechargeable battery when fully charged, and the amount of electric charge is expressed in ampere-hours (Ah). In other words, the FCC is the amount of electric charge, expressed in ampere-hours (Ah), that is dischargeable from the rechargeable battery from a fully charged state to a fully discharged state. The ratio of the remaining capacity (RC), expressed in ampere-hours (Ah), of the rechargeable battery to the full charge capacity (FCC), expressed in ampere-hours (Ah), is referred to as the state of charge (SOC) (%). When the FCC (Ah) decreases, the SOC (%) changes even if the voltage (V) is the same. In general, charging and discharging of a rechargeable battery are controlled based on the SOC (%). Therefore, accurate estimation of the FCC (Ah) is significant for accurate estimation of the SOC (%).

JP2023-030328A describes a battery management device that uses an electric circuit model of a battery. The device includes a controller, which calculates an index related to the battery, and a processor, which uses a filter having a variable gain to estimate parameters of the electric circuit model based on the battery temperature and the amount of change in the current flowing through the battery.

JP 2020-508442A describes a device and a method for estimating the state of charge of a battery in which a processor adjusts a process noise covariance used by an extended Kalman filter with operating characteristics of the battery. The state of charge of the battery is estimated based on the adjusted process noise covariance.

JP2023-541417A describes a method for estimating the state of a battery in which a Kalman filter processor uses measurement values from a voltage sensor, a current sensor, and a temperature sensor provided for the battery, and a battery equivalent circuit model stored in a battery equivalent circuit model recording unit. The method includes sequentially estimating a charge rate of the battery, a capacity deterioration rate of the battery, a current offset of a current sensor, and an internal resistance of the battery, which is set in the battery equivalent circuit model. Further, the method includes varying a system noise covariance used by the Kalman filter processor in accordance with deterioration of the battery.

In the techniques described above, the extended Kalman filter allows for the estimation of the battery state.

### SUMMARY

The characteristics of a lithium-ion battery differ between, for example, a high SOC region and a low SOC region. Thus, a process noise parameter used by the filter may be weighted differently between the high SOC region and the low SOC region.

Accordingly, a process noise parameter used by the filter may be weighted differently between the high SOC region and the low SOC region. Such a shortcoming is not limited to lithium-ion batteries and also occurs in other types of rechargeable batteries.

One general aspect is a method for estimating a state of a lithium-ion battery with a control device including a computer to converge a voltage error using an adaptive filter. The adaptive filter includes, as parameters, a standard deviation Qₚ of process noise and a standard deviation Rₚ of measurement noise that are related to correction of a positive-electrode solid-phase average ion concentration C_{s,ave,p}, and a standard deviation Qₙ of process noise and a standard deviation Rₙ of measurement noise that are related to correction of a negative-electrode solid-phase average ion concentration C_{s,ave,n}. With respect to a positive-electrode OCP curve OCPₚ indicating a positive-electrode open-circuit potential Vₚ (V) in a positive-electrode solid-phase average ion concentration ratio θₚ and a negative-electrode OCP curve OCPₙ indicating a negative-electrode open-circuit potential Vₙ (V) in a negative-electrode solid-phase average ion concentration ratio θₙ, an absolute value of a derivative dVₚ/dθₚ of the positive-electrode OCP curve OCPₚ is multiplied by a ratio of the standard deviation Qₚ and the standard deviation Rₚ, and an absolute value of a derivative dVₙ/dθₙ of the negative-electrode OCP curve OCPₙ is multiplied by a ratio of the standard deviation Qₙ and the standard deviation Rₙ. The method includes changing a correction sensitivity of the positive-electrode solid-phase average ion concentration C_{s,ave,p} and the negative-electrode solid-phase average ion concentration C_{s,ave,n} that change in accordance with a state of charge (SOC) of the rechargeable battery.

The method further includes setting the positive-electrode solid-phase average ion concentration C_{s,ave,p} and the negative-electrode solid-phase average ion concentration C_{s,ave,n} that have been corrected; obtaining the positive-electrode solid-phase average ion concentration ratio θₚ and the negative-electrode solid-phase average ion concentration ratio θₙ from the positive-electrode solid-phase average ion concentration C_{s,ave,p} and the negative-electrode solid-phase average ion concentration C_{s,ave,n} that have been set; shifting the positive-electrode OCP curve OCPₚ and the negative-electrode OCP curve OCPₙ so that the positive-electrode solid-phase average ion concentration ratio θₚ matches the negative-electrode solid-phase average ion concentration ratio θₙ in the positive-electrode OCP curve OCPₚ and the negative-electrode OCP curve OCPₙ; obtaining a difference of the positive-electrode open-circuit potential Vₚ (V) and the negative-electrode open-circuit potential Vₙ (V), searching the positive-electrode solid-phase average ion concentration ratio θₚ and the negative-electrode solid-phase average ion concentration ratio θₙ for a voltage set as a lowest voltage VL (V) and a voltage set as a highest voltage VH (V), and setting the positive-electrode solid-phase average ion concentration ratio θₚ and the negative-electrode solid-phase average ion concentration ratio θₙ, which corresponds to the lowest voltage VL (V), to θ₀ and the positive-electrode solid-phase average ion concentration ratio θₚ and the negative-electrode solid-phase average ion concentration ratio θₙ, which corresponds to the highest voltage VH (V), to θ₁₀₀; and in the positive-electrode OCP curve OCPₚ indicating the positive-electrode open-circuit potential Vₚ (V) in the positive-electrode solid-phase average ion concentration ratio θₚ and in the negative-electrode OCP curve OCPₙ indicating the negative-electrode open-circuit potential Vₙ (V) in the negative-electrode solid-phase average ion concentration ratio θₙ, calculating the SOC (%) according to the following equation:

$$SOC = \frac{{θ}_{p} - {θ}_{0}}{{θ}_{100} - {θ}_{0}} \times 100. \qquad ( 1 )$$

The method further includes, in the positive-electrode OCP curve OCPₚ indicating the positive-electrode open-circuit potential Vₚ in the positive-electrode solid-phase average ion concentration ratio θₚ and in the negative-electrode OCP curve OCPₙ indicating the negative-electrode open-circuit potential Vₙ in the negative-electrode solid-phase average ion concentration ratio θₙ, based on the positive-electrode solid-phase average ion concentration ratio θₚ and the negative-electrode solid-phase average ion concentration ratio θₙ that are based on the positive-electrode solid-phase average ion concentration and the negative-electrode solid-phase average ion concentration, where ε_{s,p} represents a positive-electrode volume fraction, Lₚ represents a positive-electrode active material thickness, Aₛ represents the coated portion area, and F represents the Faraday constant, calculating a full charge capacity (FCC) (Ah) according to the following equation:

$$FCC = ( {θ}_{100} - {θ}_{0} ) \times \frac{{C}_{s , max , p} {ε}_{s , p} {L}_{p} {A}_{s} F}{3600} . \qquad ( 2 )$$

The adaptive filter is a Kalman filter.

The rechargeable battery is a lithium-ion battery, and ions are lithium (Li) ions.

Other features and aspects will be apparent from the following detailed description, the drawings, and the claims.

### BRIEF DESCRIPTION OF THE DRAWINGS

FIG. 1 is a block diagram illustrating a device for estimating the state of a lithium-ion battery.

FIG. 2 is a flowchart illustrating a method for estimating the state of a lithium-ion battery.

FIG. 3A is a graph illustrating the relationship between the solid-phase average ion concentration ratio θ and the open-circuit potential OCP (V), and FIG. 3B is a graph illustrating the relationship between the solid-phase average ion concentration ratio θ and the absolute value of the derivative dV/dθ of the open-circuit potential OCP (V).

FIG. 4 is a graph illustrating the relationship between the solid-phase average ion concentration ratio θ and the open-circuit potential OCP (V).

FIG. 5 is a schematic diagram of a single-particle model in which a positive-electrode active material or a negative-electrode active material is assumed to be a single perfect sphere.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

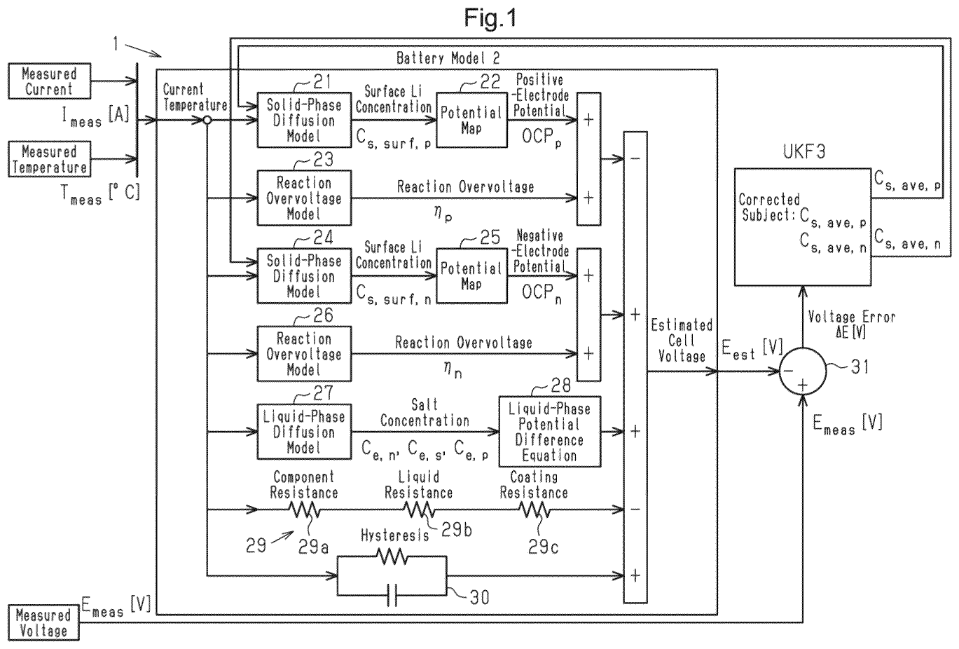

A method for estimating the state of a rechargeable battery will now be described with reference to FIGS. 1 to 4. The described and illustrated embodiment is an example of a method for estimating the FCC (Ah) and SOC (%) of a lithium-ion battery using lithium ions Li⁺ as carrier ions. The present invention is not limited to the present embodiment.

### Outline of Present Embodiment

As described in the Background section, known methods for estimating the FCC (Ah) and the SOC (%) use an adaptive filter such as an extended Kalman filter. Although various types of adaptive filters may be used in the method for estimating the FCC and the SOC of the lithium-ion battery in accordance with the present invention, a typical unscented Kalman filter (UKF) is used in the present embodiment. The UKF is a sophisticated recursive algorithm used to estimate the state of a nonlinear dynamic system. The UKF differs from an extended Kalman filter that relies on linear approximation. The UKF uses deterministic sampling to obtain a mean and a covariance of a state distribution. One main advantage of the UKF is that it handles a nonlinear system more efficiently than a filter based on linear approximation. The UKF will not be described in detail.

FIG. 1 is a block diagram illustrating a device for estimating the state of a lithium-ion battery. As shown in FIG. 1, in the method for estimating the FCC and the SOC of the lithium-ion battery according to the present embodiment, a state estimating device 1 includes a battery model 2 used to calculate and estimate an open-circuit voltage OCV (V). A voltage error ΔE (V) is calculated from the estimated voltage Eₑₛₜ (V), which is an estimated measurement, and a measured voltage Eₘₑₐₛ (V), which is an actual sensor measurement.

A UKF processor 3 corrects a positive-electrode solid-phase average ion concentration C_{s,ave,p} and a negative-electrode solid-phase average ion concentration C_{s,ave,n} based on the voltage error ΔE (V) to reduce the voltage error ΔE (V). The SOC (%) and the FCC (Ah) are estimated based on the estimated voltage Eₑₛₜ (V), which is obtained from the corrected positive-electrode solid-phase average ion concentration C_{s,ave,p} and the corrected negative-electrode solid-phase average ion concentration C_{s,ave,n}.

### Principle of Present Embodiment

The UKF has set values that include a standard deviation Q of process noise and a standard deviation R of measurement noise. In general, these standard deviations are fixed values set in accordance with the expected variability of the subject parameters. In the present embodiment, there are two parameters that are subject to correction by the UKF: the positive-electrode solid-phase average ion concentration C_{s,ave,p} and the negative-electrode solid-phase average ion concentration C_{s,ave,n}. The parameters of the UKF include the standard deviation Qₚ of process noise and the standard deviation Rₚ of measurement noise that are related to the correction of the positive-electrode solid-phase average ion concentration C_{s,ave,p}. The parameters of the UKF also include the standard deviation Qₙ of process noise and the standard deviation Rₙ of measurement noise that are related to the correction of the negative-electrode solid-phase average ion concentration C_{s,ave,n}. In this description, the standard deviation Q_{Cs,ave,p} of process noise related to the positive-electrode solid-phase average ion concentration C_{s,ave,p} may be simply referred to as the standard deviation Qₚ. Further, the standard deviation Q_{Cs,ave,n} of process noise related to the negative-electrode solid-phase average ion concentration C_{s,ave,n} may be simply referred to as the standard deviation Qₙ. The standard deviation Qₚ and the standard deviation Qₙ may be collectively referred to as the standard deviation Q.

The standard deviation Rₚ of measurement noise of the positive electrode and the standard deviation Rₙ of measurement noise of the negative electrode are maintained as fixed values.

In contrast, the standard deviation Qₚ of the positive electrode and the standard deviation Qₙ of the negative electrode are varied. The feature of the present embodiment is in the adjustment of these values.

The standard deviations used to weight, for example, the errors of the positive-electrode solid-phase average ion concentration C_{s,ave,p} and the negative-electrode solid-phase average ion concentration C_{s,ave,n} vary depending on the situation, such as the SOC. Thus, the originally set standard deviations Qₚ and Qₙ may become improper.

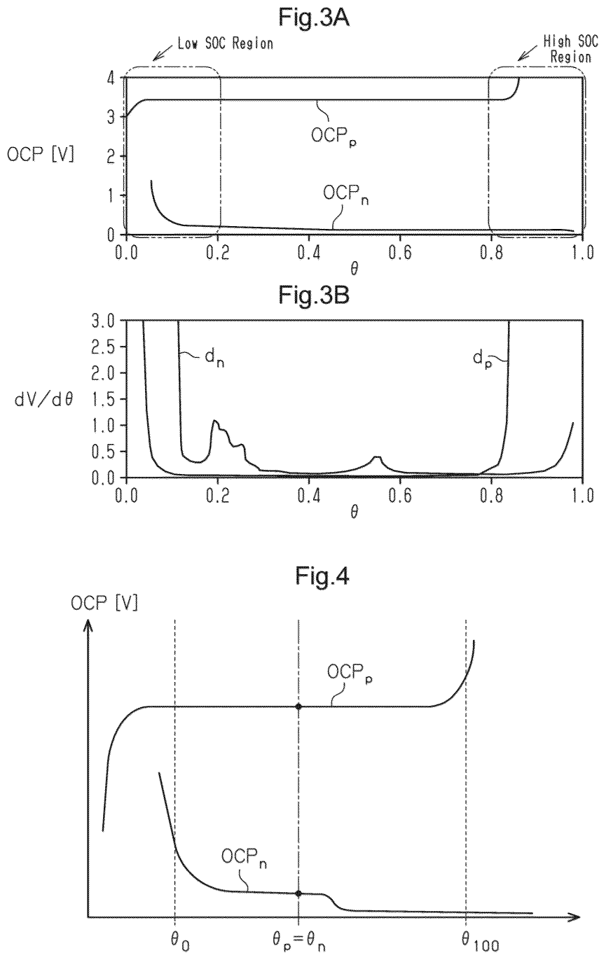

FIG. 3A is a graph illustrating the relationship between the solid-phase average ion concentration ratio θ and the open-circuit potential OCP (V). FIG. 3B is a graph illustrating the relationship between the solid-phase average ion concentration ratio θ and the absolute value of the derivative dV/dθ of the open-circuit potential OCP (V).

FIG. 3A shows a positive-electrode OCP curve OCPₚ and a negative-electrode OCP curve OCPₙ. In this description, the positive-electrode OCP curve OCPₚ and the negative-electrode OCP curve OCPₙ may be collectively referred to as the OCP curve. Further, a positive-electrode open-circuit potential Vₚ and a negative-electrode open-circuit potential Vₙ may be collectively referred to as the open-circuit potential OCP (V). The open-circuit voltage OCV (V) is derived from the positive-electrode OCP curve OCPₚ and the negative-electrode OCP curve OCPₙ. The horizontal axis represents the negative-electrode solid-phase average ion concentration ratio θₙ and is substantially equal to the SOC (%). The upper positive-electrode OCP curve OCPₚ indicates the positive-electrode open-circuit potential Vₚ (V). The lower negative-electrode OCP curve OCPₙ indicates the negative-electrode open-circuit potential Vₙ (V). Here, θ represents the ratio of a solid-phase average ion concentration C_{s,ave} to a solid-phase maximum ion concentration C_{s,MAX}, as indicated in Equation 3, which is shown below.

Moreover, θₚ represents the ratio of the positive-electrode solid-phase average ion concentration C_{s,ave.p} to the positive-electrode solid-phase maximum ion concentration C_{s,MAX.p}. Further, θₙ represents the ratio of the negative-electrode solid-phase average ion concentration C_{s,ave.n} to the negative electrode solid-phase maximum ion concentration C_{s,MAX.n}.

In this case, C_{s,MAX.n} represents the total amount of lithium ions Li⁺ that can be inserted into a negative-electrode active material EMPₙ, as determined by its physical property. Further, C_{s,MAX.p} represents the total amount of lithium ions Lit that can be inserted into a positive-electrode active material EMPₚ, as determined by its physical property. In the present embodiment, the solid-phase average ion concentration at the positive electrode is represented by C_{s,ave,p}. The subscript indicating polarity is “ₚ” for the positive electrode and “ₙ” for the negative electrode. The solid-phase average ion concentration during a time step k is represented by C_{s,ave,p}(k). The same applies to the following.

$$θ = \frac{{C}_{s , ave}}{{C}_{s , M A X}} \qquad ( 3 )$$

Accordingly, for a negative electrode, θ=0.0 indicates a state in which there are no lithium ions Li⁺ in the negative-electrode active material EMPₙ, that is, SOC=0(%). In contrast, θ=1.0 indicates a state in which the maximum amount of lithium ions Li⁺ is inserted into the negative-electrode active material EMPₙ, that is, SOC=100(%). In FIG. 3A, the right-hand region enclosed by the double-dashed line indicates a high SOC region of the battery. Further, in FIG. 3A, the left-hand region enclosed by the double-dashed line indicates a low SOC region of the battery.

As shown in FIG. 3A, the voltage error ΔE (V), which results from the shapes of the positive-electrode OCP curve OCPₚ and the negative-electrode OCP curve OCPₙ, are caused by factors that differ between the low SOC region at the left side and the high SOC region at the right side. More specifically, as the open-circuit voltage OCV (V) decreases, that is, as the SOC (%) decreases in the leftward direction, a large change first occurs in the negative-electrode OCP curve OCPₙ of the negative-electrode open-circuit potential Vₙ (V). This increases the weight of the negative-electrode solid-phase average ion concentration C_{s,ave,n} on accurate estimation of the open-circuit voltage OCV (V).

As the open-circuit voltage OCV (V) increases, that is, as the SOC (%) increases in the rightward direction, a large change first occurs in the positive-electrode OCP curve OCPₚ of the positive-electrode open-circuit potential Vₚ (V). This also increases the weight of the positive-electrode solid-phase average ion concentration C_{s,ave,p} on accurate estimation of the open-circuit voltage OCV (V).

The dV/dθ curves shown in FIG. 3B indicate the weights on the positive-electrode open-circuit potential Vₚ (V) and the negative-electrode open-circuit potential Vₙ (V). FIGS. 3A and 3B are based on actual measurement results taken by the inventors. In the same manner as FIG. 3A, the horizontal axis represents the negative-electrode solid-phase average ion concentration ratio θₙ. The dV/dθ curve indicates the relationship between the negative-electrode solid-phase average ion concentration ratio θₙ and the derivative dV/de. The dV/dθ curve of the positive electrode is shown by curve dₚ, and the dV/dθ curve of the negative electrode is shown by curve dₙ. In FIG. 3B, when proceeding to the right and entering the high SOC region, a large change first occurs in curve dₚ, which is the dV/de curve of the positive electrode. This increases the weight of the positive-electrode solid-phase average ion concentration C_{s,ave,p} on accurate estimation of the open-circuit voltage OCV (V). In FIG. 3B, when proceeding to the left and entering the low SOC region, a large change first occurs in curve dₙ, which is the dV/dθ curve of the negative electrode. This increases the weight of the negative-electrode solid-phase average ion concentration C_{s,ave,n} on accurate estimation of the open-circuit voltage OCV (V). As described above, the graph of FIG. 3B shows that in the high SOC region, curve dₚ changes greatly, and the weight of the positive electrode is large. In the low SOC region, curve dₙ changes greatly, and the weight of the negative electrode is large.

In the UKF, a greater standard deviation Q of process noise increases the correction. Thus, the standard deviation Qₚ of process noise, which is related to the correction of the positive-electrode solid-phase average ion concentration C_{s,ave,p}, is multiplied by the dV/dθ value of the positive-electrode open-circuit potential Vₚ. Further, the standard deviation Qₙ of process noise, which is related to the correction of the negative-electrode solid-phase average ion concentration C_{s,ave,n}, is multiplied by the dV/de value of the negative-electrode open-circuit potential Vₙ. Thus, the parameters having a higher weight are corrected more greatly.

In the method for estimating the state of the lithium-ion battery, the standard deviations Qₚ and Qₙ of the positive electrode and the negative electrode are changed in accordance with the situation, such as the SOC.

The positive-electrode solid-phase average ion concentration C_{s,ave,p} and the negative-electrode solid-phase average ion concentration C_{s,ave,n}, which are subject to correction, are parameters having a close relationship with the open-circuit voltage OCV (V). Thus, the absolute value of the derivative dVₚ/dθₚ of the positive-electrode OCP curve OCPₚ is multiplied by the ratio of the standard deviation Qₚ and the standard deviation Rₚ, and the absolute value of the derivative dVₙ/dθₙ of the negative-electrode OCP curve OCPₙ is multiplied by the ratio of the standard deviation Qₙ and the standard deviation Rₙ. This changes the correction sensitivities of the positive-electrode solid-phase average ion concentration C_{s,ave,p} and the negative-electrode solid-phase average ion concentration C_{s,ave,n}, which are varied in accordance with the SOC (%). Further, this reflects the weight on errors that changes in accordance with the situation. As a result, the SOC (%) and the FCC (Ah) are estimated with further accuracy from the corrected positive-electrode solid-phase average ion concentration C_{s,ave,p} and the corrected negative-electrode solid-phase average ion concentration C_{s,ave,n}.

As described above, the standard deviation Q is changed in accordance with the situation such as the SOC (%). The positive-electrode solid-phase average ion concentration C_{s,ave,p} and the negative-electrode solid-phase average ion concentration C_{s,ave,n}, which are subject to correction, are parameters closely related to the open-circuit potential OCP (V). Thus, the absolute value of the derivative dVₚ/dθₚ of the positive-electrode OCP curve OCPₚ is multiplied by the ratio of the standard deviation Qₚ and the standard deviation Rₚ, and the absolute value of the derivative dVₙ/dθₙ of the negative-electrode OCP curve OCPₙ is multiplied by the ratio of the standard deviation Qₙ and the standard deviation Rₙ. This reflects the weight on errors that changes in accordance with situations such as the SOC (%). Accordingly, the method for estimating the state of the lithium-ion battery in accordance with the present embodiment allows for accurate estimation.

### Configuration of the Present Embodiment

### State Estimating Device 1 for Lithium-Ion Battery

FIG. 1 is a block diagram showing the state estimating device 1 for a lithium-ion battery in accordance with the present embodiment. FIG. 1 shows only the main parts and does not show known parts that are not necessary for the description of the present embodiment, such as a control device that includes a computer and controls the state estimating device 1, a storage device that stores data and programs, and a charging-discharging device that charges and discharges a battery.

The state estimating device 1, inputs, to the battery model 2, a measured current Iₘₑₐₛ (A), which is detected by an ammeter (not shown), and a measured temperature Tₘₑₐₛ (° C.), which is detected by a thermometer (not shown), received from the lithium-ion battery that is being tested.

### Battery Model 2

The battery model 2 simulates the state of the actual internal voltage E (V) of the lithium-ion battery based on the measured current Iₘₑₐₛ (A) and the measured temperature Tₘₑₐₛ (° C.). The estimated voltage Eₑₛₜ (V) is estimated from the simulation result. The battery model 2 includes a positive-electrode solid-phase diffusion model 21, a reaction overvoltage model 23, a negative-electrode solid-phase diffusion model 24, a reaction overvoltage model 26, a liquid-phase diffusion model 27, an internal resistance model 29, and a hysteresis model 30.

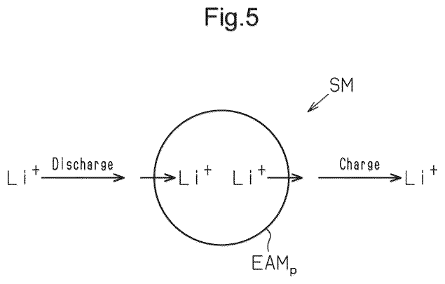

FIG. 5 is a schematic diagram of a single-particle model in which a positive-electrode active material EAMₚ is assumed to be a single perfect sphere. The positive-electrode solid-phase diffusion model 21 estimates the positive-electrode solid-phase average ion concentration C_{s,ave,p}. A single-particle model SM, which is shown in FIG. 5 and assumes that the positive-electrode active material EAMₚ is a single perfect sphere, is used to define the positive-electrode solid-phase average ion concentration C_{s,ave,p}. When the battery is charged, lithium ions Li⁺ are extracted from the positive-electrode active material EAMₚ. When the battery is discharged, lithium ions Li⁺ are inserted into the positive-electrode active material EAMₚ. The positive-electrode solid-phase ion concentration C_{s,p} is not uniform in the positive-electrode active material EAMₚ. The average value of the positive-electrode solid-phase ion concentration C_{s,p} is defined as the positive-electrode solid-phase average ion concentration C_{s,ave,p}.

$${C}_{s , ave , p} ( k ) = {C}_{s , ave , p} ( k - 1 ) + \frac{3}{{A}_{s} {L}_{p} {a}_{s , p} {r}_{s , p} F} l \cdot Δ t \qquad ( 4 )$$

C_{s,ave,p}: Positive Average Ion Concentration
qₚ: Positive-Electrode Solid-Phase Li Ion Concentration Difference
C_{s,surf,p}: Positive-Electrode Solid-Phase Surface Ion Concentration
Aₛ: Coated Portion Area
Lₚ: Positive-Electrode Active Material Thickness
a_{s,p}: Specific Surface Area
r_{s,p}: Positive-Electrode Solid-Phase Particle Radius
Dₛ: Positive-Electrode Solid-Phase Diffusion Coefficient
F: Faraday Constant
L: Current
Δt: Sampling Time

Equation 4, which is shown above, is used to obtain the positive-electrode solid-phase average ion concentration C_{s,ave,p}. Equation 4 allows the positive-electrode solid-phase average ion concentration C_{s,ave,p} at time step k to be estimated logically.

The positive-electrode open-circuit potential Vₚ (V), however, is directly affected by a positive-electrode solid-phase surface ion concentration C_{s,surf,p} and changed. Therefore, the positive-electrode solid-phase surface ion concentration C_{s,surf,p} is calculated from the estimated positive-electrode solid-phase average ion concentration C_{s,ave,p}. The Equations 5 and 6, which are shown below, are conversion equations for calculating the positive-electrode solid-phase surface ion concentration C_{s,surf,p} from the positive-electrode solid-phase average ion concentration C_{s,ave,p} at time step k.

$${q}_{P} ( k ) = ( 1 - 35 \frac{{D}_{s}}{{r}_{s , p}^{2}} Δ t ) {q}_{p} ( k - 1 ) + \frac{7}{{A}_{s} {L}_{p} {a}_{s , p} {r}_{s , p} F} l \cdot Δ t \qquad ( 5 )$$

$${C}_{s , surf , p} ( k ) = {C}_{s , ave , p} ( k ) + {q}_{p} ( k ) \qquad ( 6 )$$

A potential map 22 is used to convert the positive-electrode solid-phase surface ion concentration C_{s,surf,p} to the positive-electrode open-circuit potential Vₚ (V) corresponding to the positive-electrode solid-phase surface ion concentration C_{s,surf,p}. The map is stored in advance in a storage device of a control computer of the state estimating device 1. The positive-electrode solid-phase surface ion concentration C_{s,surf,p}, which is calculated using Equation 6, and the potential map 22 are used to determine the positive-electrode open-circuit potential Vₚ (V).

The reaction overvoltage model 23 is used to estimate a reaction overvoltage np (V), which is the voltage drop resulting from an internal reaction at the input measured current Iₘₑₐₛ (A). The reaction overvoltage model 23 is used to calculate the reaction overvoltage np (V).

The positive-electrode open-circuit potential Vₚ (V) is added to the reaction overvoltage np (V).

The negative-electrode solid-phase diffusion model 24 calculates the negative-electrode solid-phase average ion concentration C_{s,ave,n}. In the same manner as the positive electrode, for the negative electrode, the single-particle model SM shown in FIG. 5 assumes that the negative-electrode active material EAMₙ is a single perfect sphere. The single-particle model SM is used to define the negative-electrode solid-phase average ion concentration C_{s,ave,n}. When the battery is discharged, lithium ions Li⁺ are extracted from the negative-electrode active material EAMₙ. When the battery is charged, lithium ions Li⁺ are inserted into the negative-electrode active material EAMₙ. The negative-electrode solid-phase ion concentration C_{s,n} is not uniform in the negative-electrode active material EAMₙ. The average value of the negative-electrode solid-phase ion concentration C_{s,n} is defined as the negative-electrode solid-phase average ion concentration C_{s,ave,n}. This is estimated logically with Equation 4 in the same manner as the positive electrode.

The negative-electrode open-circuit potential Vₙ (V), however, is directly affected by a negative-electrode solid-phase surface ion concentration C_{s,surf,n}. Therefore, the negative-electrode solid-phase surface ion concentration C_{s,surf,n} is calculated from the estimated negative-electrode solid-phase average ion concentration C_{s,ave,n}.

A potential map 25 is used to convert the negative-electrode solid-phase surface ion concentration C_{s,surf,n} to the negative-electrode open-circuit potential Vₙ (V) corresponding to the negative-electrode solid-phase surface ion concentration C_{s,surf,n}. The map is stored in advance in the storage device of the control computer of the state estimating device 1. In the same manner as the positive electrode, for the negative electrode, the negative-electrode solid-phase surface ion concentration C_{s,surf,n}, which is calculated using equations 5 and 6, and the potential map 25 are used to determine the negative-electrode open-circuit potential Vₙ (V).

The reaction overvoltage model 26 is used to estimate the reaction overvoltage ηₙ (V), which is the voltage drop resulting from an internal reaction at the input measured current Iₘₑₐₛ (A). The reaction overvoltage model 26 is used to calculate the reaction overvoltage ηₙ (V).

The negative-electrode open-circuit potential Vₙ (V) is added to the reaction overvoltage ηₙ (V).

The liquid-phase diffusion model 27 is used to calculate the decrease in voltage caused by the lithium ions Li⁺ diffused in the nonaqueous electrolyte solution. In this case, the voltage decrease is estimated with a liquid-phase potential difference equation 28 (details not shown) based on a negative-electrode liquid-phase ion concentration C_{e,n}, a separator liquid-phase ion concentration C_{e,s}, and a positive-electrode liquid-phase ion concentration C_{e,p}.

The internal resistance model 29 is used to estimate the voltage decrease mainly caused by the resistance of metal portions such as terminals at the positive and negative electrodes. The internal resistance model 29 includes a component resistance 29a, such as a terminal and a collector, a liquid resistance 29b of a nonaqueous electrolyte solution, and a coating resistance 29c of a solid electrolyte interphase (SEI).

The hysteresis model 30 is used to estimate a voltage change resulting from the hysteresis of the battery. A rechargeable battery is prone to hysteresis, and the open-circuit voltage OCV (V), which acts as an electromotive force, is affected by past current values I (A). The hysteresis model 30 is an equivalent circuit formed by an RC circuit. The hysteresis behavior is reproduced to estimate changes in the open-circuit voltage OCV (V).

In this manner, in the present embodiment, the battery model 2 includes the positive-electrode solid-phase diffusion model 21, the reaction overvoltage model 23, the negative-electrode solid-phase diffusion model 24, the reaction overvoltage model 26, the liquid-phase diffusion model 27, the internal resistance model 29, and the hysteresis model 30. These models are used to calculate the estimated voltage Eₑₛₜ (V) of the actual lithium-ion battery from the measured current Iₘₑₐₛ (A) and the measured temperature Tₘₑₐₛ (° C.).

A voltage error calculator 31 outputs the difference between the measured voltage Eₘₑₐₛ (V), actually measured in time step k, and the estimated voltage Eₑₛₜ (V), estimated by the battery model 2, as the voltage error ΔE (V).

The voltage error calculator 31 sends the voltage error ΔE (V) to the UKF processor 3.

### UKF Processor 3

The UKF processor 3 predicts decreases in the voltage error ΔE (V) for each time step k based on the voltage error ΔE (V).

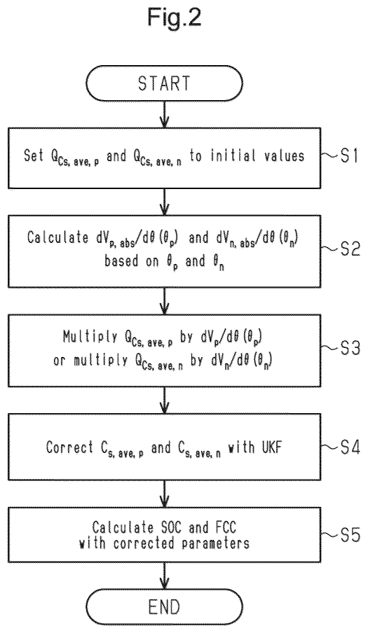

FIG. 2 is a flowchart illustrating a method for estimating the state of a lithium-ion battery in accordance with the present embodiment.

The processing contents of the UKF processor 3 will now be described. The procedures of the process performed by the UKF processor 3 will now be described with reference to the flowchart of FIG. 2.

### Preparation

Prior to processing, the positive-electrode OCP curve OCPₚ and the negative-electrode OCP curve OCPₙ, which are shown in FIG. 3A, are obtained. Further, the obtained positive-electrode OCP curve OCPₚ and negative-electrode OCP curve OCPₙ, which are shown in FIG. 3A, are each differentiated. A two-dimensional map of negative-electrode solid-phase average ion concentration ratio θₙ, the curve dₚ of dVₚ/dθ, and the curve dₙ of dVₙ/dθ is obtained. The differential curves may be obtained through an equation or through a two-dimensional map.

Setting of the Standard Deviation Q_{Cs,ave,p}, and the Standard Deviation Q_{Cs,ave,n} to Initial Values (S1)

$$\begin{matrix}{Q}_{{C}_{s , ave , p}} ( k ) = {Q}_{p , ini} , & {Q}_{{C}_{s , ave , n}} ( k ) = {Q}_{n , ini} ,\end{matrix} \qquad ( 7 )$$

The standard deviation Q_{Cs,ave,p} and the standard deviation Q_{Cs,ave,n} are each set to an initial value (S1).

In this description, the standard deviation Q_{Cs,ave,p} may be referred to as the standard deviation Qₚ, and the standard deviation Q_{Cs,ave,n} may be referred to as the standard deviation Qₙ. In this case, as indicated in Equation 7 which is shown above, the standard deviation Qₚ(k) of process noise related to correction of the positive-electrode solid-phase average ion concentration C_{s,ave,p}, which corresponds to process noise in the extended Kalman filter, in time step k is set to an initial value Q_{p_ini}. Further, the standard deviation Qₙ (k) of process noise related to correction of the negative-electrode solid-phase average ion concentration C_{s,ave,n} is set to an initial value Q_{n_ini}. Here, k represents a time step, which is when a measurement is taken. Further, k+1 indicates the next time step, and k−1 indicates the preceding step. The initial value Q_{p_ini} and the initial value Q_{n_ini} are determined when the extended Kalman filter is designed. These values are set in accordance with the subject of correction.

Then, dV_{p,abs}/dθ(θₚ) and V_{n,abs/dθ(θ}ₙ) are calculated based on θₚ and θₙ (S2).

First, the positive-electrode solid-phase average ion concentration C_{s,ave,p} (k) and the negative-electrode solid-phase average ion concentration C_{s,ave,n} (k) are each obtained from the battery model 2. The battery model 2 of the present embodiment uses the single-particle model SM such as that shown in FIG. 5. Further, θₚ(k) and θₙ(k) are calculated through Equation 8, which is shown below, based on the known negative-electrode solid-phase average ion concentration C_{s,ave,n} and positive-electrode solid-phase maximum ion concentration C_{s,max,p}. The subscript “_{abs}” represents an absolute value.

$$\begin{matrix}{θ}_{p} ( k ) = \frac{{C}_{s , ave , p} ( k )}{{C}_{s , max , p}} , & {θ}_{n} ( k ) = \frac{{C}_{s , ave , n} ( k )}{{C}_{s , max , n}} ,\end{matrix} \qquad ( 8 )$$

Then, dVₚ/dθ(θₚ(k)) and dVₙ/dθ(θₙ(k)) are derived through Equation 9, which is shown below, based on the differential curves, obtained during the preparation, and θₚ(k), and θₙ(k). Further, absolute values abs of these values are taken.

$$\begin{matrix}\frac{{d V}_{p , abs}}{d {θ}_{p}} ( k ) = \frac{{d V}_{p}}{d θ} ( {θ}_{p} ( k ) ) , & \frac{{d V}_{n , abs}}{d {θ}_{n}} ( k ) = \frac{{d V}_{n}}{d θ} ( {θ}_{n} ( k ) )\end{matrix} \qquad ( 9 )$$

The standard deviation Q_{Cs,ave,p} is multiplied by dVₚ/dθ(θₚ). Further, Q_{Cs,ave,n} is multiplied by dVₙ/dθ(θₙ) (S3).

$$\begin{matrix}{Q}_{p}^{′} ( k ) = {Q}_{{C}_{s , ave , p}} \times \frac{{d V}_{p , abs}}{d {θ}_{p}} ( k ) , & {Q}_{n}^{′} ( k ) = {Q}_{{C}_{s , ave , n}} \times \frac{{d V}_{n , abs}}{d {θ}_{n}} ( k )\end{matrix} \qquad ( 10 )$$

Then, as shown in Equation 10 which is shown above, the standard deviation Q_{Cs,ave,p} is multiplied by dV_{p,abs}/dθₚ(k) to obtain a standard deviation Q′p(k). In the same manner, the standard deviation Q_{Cs,ave,n} is multiplied by dV_{n,abs}/dθₙ(k) to obtain a standard deviation Q′ₙ(k).

The standard deviation Q′ₚ(k) and the standard deviation Q′ₙ(k) are set as the standard deviation Q of process noise used by the UKF in time step K.

The nonlinear Kalman filter corrects C_{s,ave,p} and C_{s,ave,n} (S4).

The UKF, which is a nonlinear Kalman filter, corrects the positive-electrode solid-phase average ion concentration C_{s,ave,p} and the negative-electrode solid-phase average ion concentration C_{s,ave,n} (S4). Further, Q′ₚ(k) and Q′ₙ(k), which are obtained in S3, are set as the standard deviation Q′ᵢ(k) of process noise of the UKF.

In this case, C_{s,offset,p} and C_{s,offset,n} respectively indicate the amount of change in the solid-phase average ion concentration of the positive electrode and the negative electrode resulting from correction.

Accordingly, Equation 11, which is shown below, is a discrete-time internal parameter updating equation.

$${[ \begin{matrix}{C}_{s , ave , p} \\ {C}_{s , offset , p} \\ {C}_{s , ave , n} \\ {C}_{s , offset , n}\end{matrix} ]}_{k} = {[ \begin{matrix}1 & 1 & 0 & 0 \\ 0 & 0 & 0 & 0 \\ 0 & 0 & 1 & 1 \\ 0 & 0 & 0 & 0\end{matrix} ] [ \begin{matrix}{C}_{s , ave , p} \\ {C}_{s , offset , p} \\ {C}_{s , ave , n} \\ {C}_{s , offset , n}\end{matrix} ]}_{k - 1} \qquad ( 11 )$$

Equation 12, which is shown below, is the output updating equation.

$${V}_{ceil} ( k ) = {\begin{matrix}[ \frac{\partial {V}_{ceil}}{\partial {C}_{s , ave , p}} & \frac{\partial {V}_{ceil}}{\partial {C}_{s , offset , p}} & \frac{\partial {V}_{ceil}}{\partial {C}_{s , ave , n}} & \frac{\partial {V}_{ceil}}{\partial {C}_{s , offset , n}} ]\end{matrix} [ \begin{matrix}{C}_{s , ave , p} \\ {C}_{s , offset , p} \\ {C}_{s , ave , n} \\ {C}_{s , offset , n}\end{matrix} ]}_{k} \qquad ( 12 )$$

Here, V_{cell} represents the estimated cell voltage (V). That is, the estimated voltage Eₑₛₜ (V).

The parameters subject to correction are C_{s,ave,p} and C_{s,ave,n}. Therefore, the state variable x(k) in the calculation performed by the UKF is as shown in Equation 13, which is shown below.

$$x ( k ) = [ \begin{matrix}{C}_{s , ave , p} \\ {C}_{s , ave , n}\end{matrix} ] \qquad ( 13 )$$

Here, g(k) represents the Kalman gain and is derived by the UKF. Further, y(k) represents the measured voltage, and y\hat{ }-(k) represents the estimated cell voltage.

Accordingly, the estimated state value of the UKF is as shown in Equation 14, which is shown below.

$$\hat{x} ( k ) = {\hat{x}}^{-} ( k ) + g ( k ) \{ y ( k ) - {\hat{y}}^{-} ( k ) \} \qquad ( 14 )$$

The corrected parameters are used to calculate the SOC and the FCC (S5).

FIG. 4 is a graph showing the relationship of the solid-phase average ion concentration ratio θ and the open-circuit potential OCP (V). The horizontal axis represents the solid-phase average ion concentration ratio θ, and the vertical axis represents the potential (V).

As described above, the SOC and the FCC are calculated (S5) based on the estimated voltage Eₑₛₜ (V) that is estimated from the estimated standard deviation Q′ₚ(k) and the estimated the standard deviation Q′ₙ(k), which are the parameters corrected in S4.

In this case, the parameters subject to correction are C_{s,ave,p} and C_{s,ave,n}, which are properly corrected in S4. Thus, the positive-electrode solid-phase average ion concentration ratio θₚ and the negative-electrode solid-phase average ion concentration ratio θₙ are each estimated accurately. As shown in FIG. 4, the positive-electrode solid-phase average ion concentration ratio θₚ and the negative-electrode solid-phase average ion concentration ratio θₙ are located at the same position in the positive-electrode OCP curve OCPₚ and the negative-electrode OCP curve OCPₙ. This allows the values of θ₀ and θ₁₀₀ to be obtained accurately.

The procedures described below are executed to obtain the SOC (%).

The positive-electrode solid-phase average ion concentration C_{s,ave,p} and the negative-electrode solid-phase average ion concentration C_{s,ave,n}, which have been corrected, are set. Based on the set positive-electrode solid-phase average ion concentration C_{s,ave,p} and the set negative-electrode solid-phase average ion concentration C_{s,ave,n}, the positive-electrode solid-phase average ion concentration ratio θₚ and the negative-electrode solid-phase average ion concentration ratio θₙ are obtained. The positive-electrode OCP curve OCPₚ and the negative-electrode OCP curve OCPₙ are shifted so that the positive-electrode solid-phase average ion concentration ratio θₚ matches the negative-electrode solid-phase average ion concentration ratio θₙ in the positive-electrode OCP curve OCPₚ and the negative-electrode OCP curve OCPₙ. The difference between the positive-electrode open-circuit potential Vₚ (V) and the negative-electrode open-circuit potential Vₙ (V) is obtained. The positive-electrode solid-phase average ion concentration ratio θₚ and the negative-electrode solid-phase average ion concentration ratio θₙ are searched for the voltage set as the lowest voltage VL (V) and the voltage set as the highest voltage VH (V). The positive-electrode solid-phase average ion concentration ratio θₚ and the negative-electrode solid-phase average ion concentration ratio θₙ corresponding to the lowest voltage VL (V) is set to θ₀, and The positive-electrode solid-phase average ion concentration ratio θₚ and the negative-electrode solid-phase average ion concentration ratio θₙ corresponding to the highest voltage VH (V) is set to θ₁₀₀.

Given the positive-electrode OCP curve OCPₚ indicating the positive-electrode open-circuit potential Vₚ (V) in the positive-electrode solid-phase average ion concentration ratio θₚ and given the negative-electrode OCP curve OCPₙ indicating the negative-electrode open-circuit potential Vₙ (V) in the negative-electrode solid-phase average ion concentration ratio θₙ, the SOC (%) is obtained through Equation 1, which is shown below.

$$SOC = \frac{{θ}_{p} - {θ}_{0}}{{θ}_{100} - {θ}_{0}} \times 100 \qquad ( 1 )$$

Equation 1 is used to obtain the SOC (%) from the positive-electrode solid-phase average ion concentration ratio θₚ. In the positive-electrode OCP curve OCPₚ and the negative-electrode OCP curve OCPₙ, the positive-electrode solid-phase average ion concentration ratio θₚ is obtained based on the corrected positive-electrode solid-phase average ion concentration C_{s,ave,p}. Further, the negative-electrode solid-phase average ion concentration ratio θₙ is obtained based on the corrected negative-electrode solid-phase average ion concentration C_{s,ave,n}. This allows the values of θ₀, θ₁₀₀, θₚ to be estimated accurately. The SOC (%) is calculated based on the matching positions of θₚ and θₙ. In equation 1, values are substituted in θ₀, θ₁₀₀, and θₚ, which are estimated accurately, to calculate the SOC with further accuracy.

$$FCC = ( {θ}_{100} - {θ}_{0} ) \times \frac{{C}_{s , max , p} {ε}_{s , p} {L}_{p} {A}_{s} F}{3600} \qquad ( 2 )$$

Equation 2, which is shown above, is used to obtain the FCC. Here, ε_{s,p} represents the positive-electrode volume fraction, Lₚ represents the positive-electrode active material thickness, Aₛ represents the coated portion area, and F represents the Faraday constant. Accordingly, the latter term in the right-hand side is a constant. Since θ₀ and θ₁₀₀ are known, the FCC is calculated readily and accurately.

### Operation of Present Embodiment

Prior to processing, the UKF processor 3 obtains the positive-electrode OCP curve OCPₚ and the negative-electrode OCP curve OCPₙ. The positive-electrode OCP curve OCPₚ and the negative-electrode OCP curve OCPₙ are each differentiated. The standard deviation Q_{Cs,ave,p} and the standard deviation Q_{Cs,ave,n} are set to initial values (S1). Then, dV_{p,abs}/dθ(θₚ) and dV_{n,abs}/dθ(θₙ) are calculated based on θₚ and θₙ(S2). The standard deviation Q_{Cs,ave,p} is multiplied by dVₚ/dθ(θₚ). Further, Q_{Cs,ave,n} is multiplied by dVₙ/dθ(θₙ) (S3). The nonlinear Kalman filter corrects C_{s,ave,p} and C_{s,ave,n} (S4). The corrected parameters are used to calculate the SOC and the FCC (S5). Through these procedures, the standard deviations Q of the positive electrode and the negative electrode are properly changed in accordance with the situation, such as the SOC.

### Advantages of the Present Embodiment

(1) In the method for estimating the state of a lithium-ion battery of the present embodiment in accordance with the present invention, the state estimating device 1 uses the UKF to converge the voltage error ΔE (V) of the lithium-ion battery. Proper adjustment of the process noise parameters of the UKF allows the battery state to be estimated readily and accurately. Thus, the correction amount is properly changed. Further, the converging time is reduced, and the estimation is accurate. Moreover, the capacity of the subject battery can be fully utilized.
(2) The standard deviation Q_{Cs,ave,p} of process noise related to correction of the positive-electrode solid-phase average ion concentration C_{s,ave,p} is used as the process noise parameter of the UKF. The standard deviation Q_{Cs,ave,n} of process noise related to correction of the negative-electrode solid-phase average ion concentration C_{s,ave,n} is also used. The positive-electrode OCP curve OCPₚ indicating the positive-electrode open-circuit potential Vₚ (V) in the positive-electrode solid-phase average ion concentration ratio θₚ is obtained. Further, the negative-electrode OCP curve OCPₙ indicating the negative-electrode open-circuit potential Vₙ (V) in the negative-electrode solid-phase average ion concentration ratio θₙ is obtained. The absolute value of the derivative dVₚ/dθₚ of the positive-electrode OCP curve OCPₚ is multiplied by the ratio of the standard deviation Qₚ and the standard deviation Rₚ. The absolute value of the derivative dVₙ/dθₙ of the negative-electrode OCP curve OCPₙ is multiplied by the ratio of the standard deviation Qₙ and the standard deviation Rₙ. This changes the correction sensitivity of the positive-electrode solid-phase average ion concentration C_{s,ave,p} and the negative-electrode solid-phase average ion concentration C_{s,ave,n} in accordance with the SOC (%). Thus, the weight is changed in accordance with the correction amount. This allows for accurate estimation.
(3) The positive-electrode open-circuit potential Vₚ (V) in the positive-electrode solid-phase average ion concentration ratio θₚ is indicated in the positive-electrode OCP curve OCPₚ. The negative-electrode open-circuit potential Vₙ (V) in the negative-electrode solid-phase average ion concentration ratio θₙ is indicated in the negative-electrode OCP curve OCPₙ. The SOC (%) is obtained from the positive-electrode OCP curve OCPₚ and the negative-electrode OCP curve OCPₙ. Thus, the SOC (%) is estimated accurately.
(4) In FIG. 4, the positive-electrode OCP curve OCPₚ indicates the positive-electrode open-circuit potential Vₚ (V) in the positive-electrode solid-phase average ion concentration ratio θₚ. Further, the negative-electrode OCP curve OCPₙ indicates the negative-electrode open-circuit potential Vₙ (V) in the negative-electrode solid-phase average ion concentration ratio θₙ. In the positive-electrode OCP curve OCPₚ and the negative-electrode OCP curve OCPₙ, the positive-electrode solid-phase average ion concentration ratio θₚ is obtained based on the corrected positive-electrode solid-phase average ion concentration C_{s,ave,p}. Further, the negative-electrode solid-phase average ion concentration ratio θₙ is obtained based on the corrected negative-electrode solid-phase average ion concentration C_{s,ave,n}. The FCC (Ah) is calculated based on the matching positions of θp and θn. This allows the FCC (Ah) to be estimated accurately.
(5) In the present embodiment, the UKF is used as the adaptive filter. This allows the state of a battery to be estimated with higher accuracy than an extended Kalman filter. Further, the state of a battery can be estimated with less load than a Kalman particle filter.
(6) In the present embodiment, the rechargeable battery is a lithium-ion battery, and the ions are Li ions Lit. The present embodiment allows the state of such a battery to be estimated accurately.

### Modified Examples

The adaptive filter may be exemplified by, for example, a Kalman filter. In the present embodiment, a UKF is used as the adaptive filter. This, however, is not a limitation. Instead of a UKF, the state of a rechargeable battery may be estimated by a Kalman filter, an extended Kalman filter, a Kalman particle filter, an error-state Kalman filter, or the like.

In the present embodiment, the standard deviation Qₚ of process noise related to correction of the positive-electrode solid-phase average ion concentration C_{s,ave,p} is used as a process noise parameter of the adaptive filter. The standard deviation Qₙ of process noise related to correction of the negative-electrode solid-phase average ion concentration C_{s,ave,n} is also used. In addition to these parameters, other parameters may be added when applying the present invention.

In the present embodiment, a lithium-ion battery including lithium ions Li⁺ is exemplified as the rechargeable battery. The rechargeable battery of the present invention is, however, not limited in structure, composition, shape, or purpose as long as the present invention can be applied. For example, the present invention may be applied to a different type of nonaqueous electrolyte solution rechargeable battery. Further, the present invention may be applied to an alkaline rechargeable battery such as a nickel-metal hydride battery.

The present embodiment is not limited to the embodiment described above. For example, an adaptive filter may be used, and the average carrier concentrations of the positive-electrode solid-phase and the negative-electrode solid-phase may be corrected based on the voltage error ΔE (V). In this case, the ions serving as electron carriers in a rechargeable battery are, for example, Li⁺, Ni⁺, Na⁺, SO₄²⁻, and H⁺. The SOC (%) and the FCC (Ah) are estimated based on the correction.

In the present embodiment, differential curves are used in the two-dimensional maps to aid understanding of the derivative dV/dθ. This is not a limitation, and equations may be stored instead.

In the present embodiment, the battery model 2 is illustrated in FIG. 1. This, however, is not a limitation. For example, the battery model 2 is not limited in format and elements such as equivalent circuits and state equations.

In the present embodiment, for example, the positive-electrode solid-phase average ion concentration C_{s,ave,p} is defined using the single-particle model shown in FIG. 5 assuming that the positive-electrode active material EAMₚ is a single perfect sphere. When the battery is discharged, lithium ions Li⁺ are inserted into the positive-electrode active material EAMₚ. When the battery is charged, lithium ions Li⁺ are extracted from the positive-electrode active material EAMₚ. The ion concentration is not uniform in the positive-electrode active material EAMₚ, and the average value of the concentration is defined as the positive-electrode solid-phase average ion concentration C_{s,ave,p}. The positive-electrode solid-phase surface ion concentration C_{s,surf,p} is calculated from the positive-electrode solid-phase average ion concentration C_{s,ave,p} through Equations 5 and 6.

Instead, a map or table, based on actual measurements, or an approximation equation may be used to obtain the positive-electrode solid-phase surface ion concentration C_{s,surf,p} from the positive-electrode solid-phase average ion concentration C_{s,ave,p}.

The drawings are schematic and simplified to aid understanding of the present invention and are not intended to limit the present invention

The numerical values, numerical ranges, and compositions in the present embodiment are examples and are not intended to limit the present invention. The present invention may be modified and optimized by one skilled in the art, depending on the intended application.

The flowchart shown in FIG. 2 is one example, and steps may be added, deleted, exchanged, and altered.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A method for estimating a state of a lithium-ion battery with a control device including a computer to converge a voltage error using an adaptive filter, the adaptive filter including, as parameters, a standard deviation Qₚ of process noise and a standard deviation Rₚ of measurement noise that are related to correction of a positive-electrode solid-phase average ion concentration C_{s,ave,p}, and a standard deviation Qₙ of process noise and a standard deviation Rₙ of measurement noise that are related to correction of a negative-electrode solid-phase average ion concentration C_{s,ave,n}, and with respect to a positive-electrode OCP curve OCPₚ indicating a positive-electrode open-circuit potential Vₚ (V) in a positive-electrode solid-phase average ion concentration ratio θₚ and a negative-electrode OCP curve OCPₙ indicating a negative-electrode open-circuit potential Vₙ (V) in a negative-electrode solid-phase average ion concentration ratio θₙ, an absolute value of a derivative dVₚ/dθₚ of the positive-electrode OCP curve OCPₚ is multiplied by a ratio of the standard deviation Qₚ and the standard deviation Rₚ, and an absolute value of a derivative dVₙ/dθₙ of the negative-electrode OCP curve OCPₙ is multiplied by a ratio of the standard deviation Qₙ and the standard deviation Rₙ, the method comprising:
changing a correction sensitivity of the positive-electrode solid-phase average ion concentration C_{s,ave,p} and the negative-electrode solid-phase average ion concentration C_{s,ave,n} that change in accordance with a state of charge (SOC) of the rechargeable battery.

2. The method according to claim 1, further comprising:
setting the positive-electrode solid-phase average ion concentration C_{s,ave,p} and the negative-electrode solid-phase average ion concentration C_{s,ave,n} that have been corrected;
obtaining the positive-electrode solid-phase average ion concentration ratio θₚ and the negative-electrode solid-phase average ion concentration ratio θₙ from the positive-electrode solid-phase average ion concentration C_{s,ave,p} and the negative-electrode solid-phase average ion concentration C_{s,ave,n} that have been set;
shifting the positive-electrode OCP curve OCPₚ and the negative-electrode OCP curve OCPₙ so that the positive-electrode solid-phase average ion concentration ratio θₚ matches the negative-electrode solid-phase average ion concentration ratio θₙ in the positive-electrode OCP curve OCPₚ and the negative-electrode OCP curve OCPₙ;
obtaining a difference of the positive-electrode open-circuit potential Vₚ (V) and the negative-electrode open-circuit potential Vₙ (V), searching the positive-electrode solid-phase average ion concentration ratio θₚ and the negative-electrode solid-phase average ion concentration ratio θₙ for a voltage set as a lowest voltage VL (V) and a voltage set as a highest voltage VH (V), and setting the positive-electrode solid-phase average ion concentration ratio θₚ and the negative-electrode solid-phase average ion concentration ratio θₙ, which corresponds to the lowest voltage VL (V), to θ₀ and the positive-electrode solid-phase average ion concentration ratio θₚ and the negative-electrode solid-phase average ion concentration ratio θₙ, which corresponds to the highest voltage VH (V), to θ₁₀₀; and
given the positive-electrode OCP curve OCPₚ indicating the positive-electrode open-circuit potential Vₚ (V) in the positive-electrode solid-phase average ion concentration ratio θₚ and given the negative-electrode OCP curve OCPₙ indicating the negative-electrode open-circuit potential Vₙ (V) in the negative-electrode solid-phase average ion concentration ratio θₙ, calculating the SOC (%) according to the following equation:
$$SOC = \frac{{θ}_{p} - {θ}_{0}}{{θ}_{100} - {θ}_{0}} \times 100.$$

3. The method according to claim 1, further comprising:
given the positive-electrode OCP curve OCPₚ indicating the positive-electrode open-circuit potential Vₚ in the positive-electrode solid-phase average ion concentration ratio θₚ and given the negative-electrode OCP curve OCPₙ indicating the negative-electrode open-circuit potential Vₙ in the negative-electrode solid-phase average ion concentration ratio θₙ,
based on the positive-electrode solid-phase average ion concentration ratio θₚ and the negative-electrode solid-phase average ion concentration ratio θₙ that are based on the positive-electrode solid-phase average ion concentration and the negative-electrode solid-phase average ion concentration,
where ε_{s,p} represents a positive-electrode volume fraction, Lₚ represents a positive-electrode active material thickness, Aₛ represents the coated portion area, and F represents the Faraday constant,
calculating a full charge capacity (FCC) (Ah) according to the following equation:
$$FCC = ( {θ}_{100} - {θ}_{0} ) \times \frac{{C}_{s , max , p} {ε}_{s , p} {L}_{p} {A}_{s} F}{3600} .$$

4. The method according to claim 1, wherein the adaptive filter is a Kalman filter.

5. The method according to claim 1, wherein the rechargeable battery is a lithium-ion battery, and ions are lithium (Li) ions.
